(19) United States
(12) Patent Application Publication
(10) Pub. No.: US 2005/0275039 A1
(43) Pub. Date: Dec. 15, 2005

(54) Semiconductor device and method of manufacturing the same

(76) Inventor: Kazuaki Nakajima, Kamakura-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/967,159

(22) Filed: Oct. 19, 2004

(30) Foreign Application Priority Data
Jun. 10, 2004 (JP) 2004-172745

(51) Int. Cl. H01L 29/76; H01L 21/335

(52) U.S. Cl. 257/388; 438/142

(57) ABSTRACT

A semiconductor device is provided which includes a semiconductor substrate, a gate insulating film which is provided on the semiconductor substrate and contains a first metallic element and oxygen, and a gate electrode which is provided on the gate insulating film and includes a metal silicide film containing a second metallic element, and an impurity layer interposed between the gate insulating film and the metal silicide film and containing a p type impurity element, wherein a Gibbs free energy of a first system including an insulator containing the first metallic element and oxygen, the p type impurity element and silicon is smaller than a Gibbs free energy of a second system including a compound containing the first metallic element and the p type impurity element, and a silicon oxide.

### CROSS-REFERENCE TO RELATED APPLICATIONS

This application is based upon and claims the benefit of priority from prior Japanese Patent Application No. 2004-172745, filed Jun. 10, 2004, the entire contents of which are incorporated herein by reference.

### BACKGROUND OF THE INVENTION

1. Field of the Invention

The present invention relates to a semiconductor device and a method of manufacturing the same.

2. Description of the Related Art

To enhance the performance of MIS transistors, scale down of MIS transistors is indispensable. However, with scale down of MIS transistors, a leakage current (tunnel current) of a gate insulating film and depletion of a polysilicon gate electrode become great problems.

To solve such problems, it has been considered adopting a gate insulating film having a high dielectric constant, such as an Hf oxide film, and adopting a metal gate electrode. By using a gate insulating film of a high dielectric constant, the thickness of the gate insulating film can be set thick, and thus it is possible to suppress a tunnel current. Further, by adopting a metal gate electrode, it is possible to prevent depletion of the gate electrode.

However, in a gate structure using a metal electrode, there arises a new problem which is different from that in the conventional gate structure using polysilicon. In the conventional gate structure using polysilicon, a threshold voltage of a transistor depends on the impurity concentration in a channel region and the impurity concentration in the polysilicon film. In comparison with this, in the gate structure using a metal electrode, a threshold voltage of a transistor depends on the impurity concentration in a channel region and a work function of the metal gate electrode.

Therefore, it is necessary to adopt a so-called dual metal gate structure, in which two types of gate electrode materials having different work functions are used for an n type MIS transistor and a p type MIS transistor. For example, a conductive material having a work function φm lower than 4.6 eV is used for a gate electrode of the n type MIS transistor, and a conductive material having a work function φm higher than 4.6 eV is used for a gate electrode of the p type MIS transistor.

As a method of obtaining a dual metal gate structure, for example, “Dual Work Function Metal Gates Using Full Nickel Silicidation of Doped Poly-Si” J. H. Sim et al., IEEE ELECTRON DEVICE LETTERS, VOL. 24, NO. 10, OCTOBER 2003, pp 631-633 discloses a method of performing ion implantation of impurity elements into metal silicide. Specifically, As is implanted as an n type impurity into a metal silicide film in an n type MIS transistor region by ion implantation, and B is implanted as a p type impurity into a metal silicide film of a p type MIS transistor region by ion implantation. By using this method, it is possible to set the work functions of the n type MIS transistor and the p type MIS transistor to be different from each other.

However, in the method disclosed in the above document, a silicon oxide film is used as gate insulating film. If a metal oxide film, such as an Hf oxide film, is used as gate insulating film, it may cause the new problem. Therefore, the method disclosed in the above document cannot always form a MIS transistor having excellent property and reliability.

As described above, in prior art, it is difficult to obtain a semiconductor device which can optimize the work function of the gate electrode, without causing an adverse influence on the property and reliability of the transistor.

### BRIEF SUMMARY OF THE INVENTION

A semiconductor device according to a first aspect of the present invention comprises: a semiconductor substrate; a gate insulating film which is provided on the semiconductor substrate and contains a first metallic element and oxygen; and a gate electrode which is provided on the gate insulating film and includes a metal silicide film containing a second metallic element, and an impurity layer interposed between the gate insulating film and the metal silicide film and containing a p type impurity element, wherein a Gibbs free energy of a first system including an insulator containing the first metallic element and oxygen, the p type impurity element and silicon is smaller than a Gibbs free energy of a second system including a compound containing the first metallic element and the p type impurity element, and a silicon oxide.

A semiconductor device according to a second aspect of the present invention comprises: a semiconductor substrate; a gate insulating film which is provided on the semiconductor substrate and contains a first metallic element, oxygen and nitrogen; and a gate electrode which is provided on the gate insulating film and includes a metal silicide film containing a second metallic element, and an impurity layer interposed between the gate insulating film and the metal silicide film and containing a p type impurity element, wherein a Gibbs free energy of a first system including an insulator containing the first metallic element, oxygen and nitrogen, the p type impurity element and silicon is smaller than a Gibbs free energy of a second system including a compound containing the first metallic element and the p type impurity element, a compound containing the p type impurity element and nitrogen, and a silicon oxide.

A method of manufacturing a semiconductor device according to a third aspect of the present invention comprises: forming a gate insulating film containing a first metallic element and oxygen on a semiconductor substrate; forming a silicon film on the gate insulating film; introducing a p type impurity element into the silicon film; forming a metal film containing a second metallic element on the silicon film; and forming a metal silicide film containing the second metallic element by reaction between the silicon film and the metal film, and an impurity layer containing the p type impurity element between the gate insulating film and the metal silicide film, wherein a Gibbs free energy of a first system including an insulator containing the first metallic element and oxygen, the p type impurity element and silicon is smaller than a Gibbs free energy of a second system including a compound containing the first metallic element and the p type impurity element, and a silicon oxide.

A method of manufacturing a semiconductor device according to a fourth aspect of the present invention comprises: forming a gate insulating film containing a first metallic element, oxygen and nitrogen on a semiconductor substrate; forming a silicon film on the gate insulating film; introducing a p type impurity element into the silicon film; forming a metal film containing a second metallic element on the silicon film; and forming a metal silicide film containing the second metallic element by reaction between the silicon film and the metal film, and an impurity layer containing the p type impurity element between the gate insulating film and the metal silicide film, wherein a Gibbs free energy of a first system including an insulator containing the first metallic element, oxygen and nitrogen, the p type impurity element and silicon is smaller than a Gibbs free energy of a second system including a compound containing the first metallic element and the p type impurity element, a compound containing the p type impurity element and nitrogen, and a silicon oxide.

### BRIEF DESCRIPTION OF THE SEVERAL VIEWS OF THE DRAWING

FIGS. 1 to 8 are cross-sectional views which schematically illustrate steps of manufacturing a semiconductor device according to an embodiment of the present invention.

FIG. 9 is a diagram illustrating a relationship between concentrations of impurity elements and amount of change of work functions.

### DETAILED DESCRIPTION OF THE INVENTION

An embodiment of the present invention will now be described with reference to drawings.

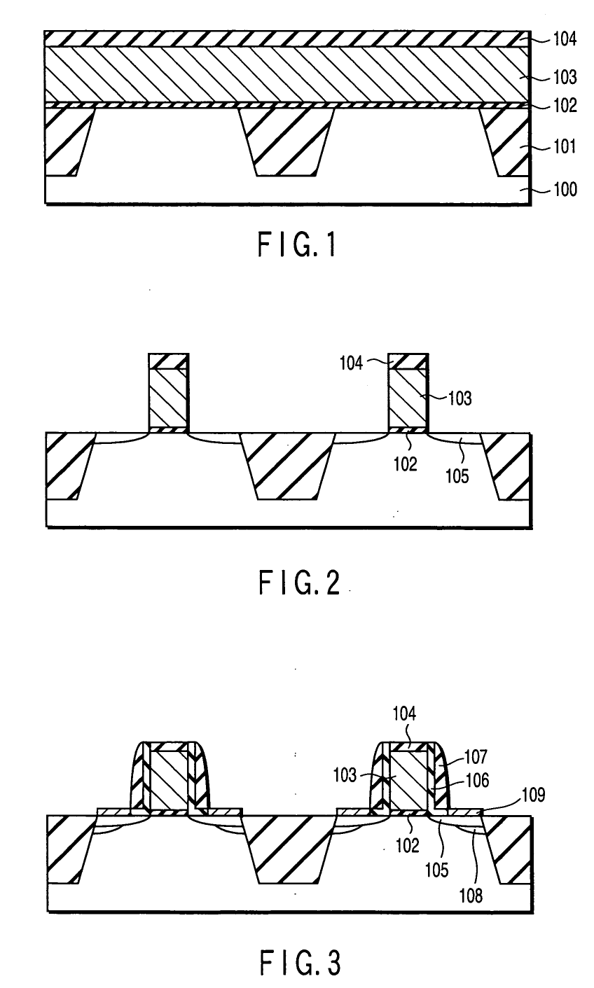

FIGS. 1 to 8 are cross-sectional views which schematically illustrate steps of manufacturing a semiconductor device (MIS transistor) according to the embodiment of the present invention.

First, as shown in FIG. 1, a hafnium oxide film (HfO₂ film) containing hafnium (a first metallic element) is formed as a gate insulating film 102 on a single-crystal silicon substrate (semiconductor substrate) 100 having isolation regions 101. A zirconium oxide film (ZrO₂ film) may be used instead of the hafnium oxide film. Thereafter, a polysilicon film 103 and a silicon nitride film 104 are deposited on the gate insulating film 102.

Next, as shown in FIG. 2, the polysilicon film 103 and the silicon nitride film 104 are subjected to anisotropic etching to form a gate electrode pattern. Thereafter, arsenic ions (As⁺ ions) are implanted into an n type MIS transistor region, and boron ions (B⁺ ions) are implanted into a p type MIS transistor region. Further, the structure is subjected to heat treatment at 800° C. for 5 seconds, and thereby source/drain low-concentration diffusion layers 105 are formed.

Next, as shown in FIG. 3, a silicon oxide film 106 and a silicon nitride film 107 are deposited on the whole surface of the structure. Then, anisotropic etching is performed to leave the silicon oxide film 106 and the silicon nitride film 107 on side surfaces of the gate electrode pattern. Thereafter, phosphorus ions (P⁺ ions) are implanted into the n type MIS transistor region, and boron ions (B⁺ ions) are implanted into the p type MIS transistor region. Further, the structure is subjected to heat treatment at 1000° C. for 5 seconds, and thereby source/drain high-concentration diffusion layers 108 are formed. Thereafter, an Ni film is formed by PVD (physical vapor deposition). Then, heat treatment is performed at 400° C. for 30 seconds to react the Ni film with the surface of the silicon substrate 100, forming an Ni silicide film 109.

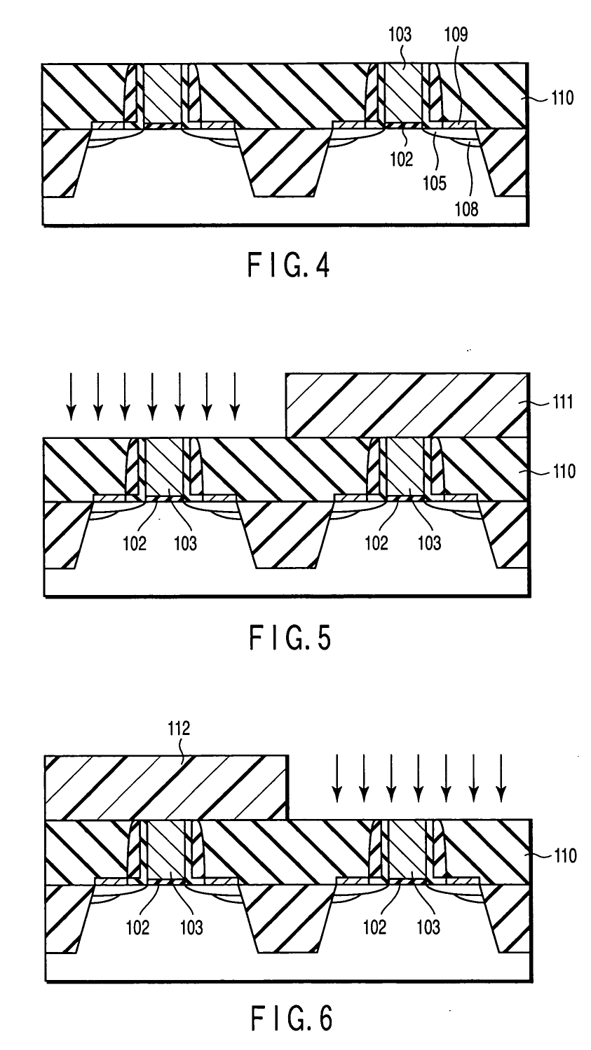

Next, as shown in FIG. 4, an interlayer insulating film 110 is deposited on the whole surface of the structure. Then, the interlayer insulating film 110 is planarized by CMP (chemical mechanical polishing). Thereby, a surface of the polysilicon film 103 is exposed.

Next, as shown in FIG. 5, a photoresist pattern 111 is formed by using photolithography. The photoresist pattern 111 covers the p type MIS transistor region, and does not cover the n type MIS transistor region. Then, with the photoresist pattern 111 used as mask, P⁺ ions or As⁺ ions are implanted into the polysilicon film 103.

Next, as shown in FIG. 6, a photoresist pattern 112 is formed by using photolithography. The photoresist pattern 112 covers the n type MIS transistor region, and does not cover the p type MIS transistor region. Thereafter, with the photoresist pattern 112 used as mask, indium ions (In⁺ ions) are implanted as p type impurity element ions into the polysilicon film 103. Gallium ions (Ga⁺ ions) may be used instead of the indium ions. Then, heat treatment is performed at 900° C. for 10 seconds. By this heat treatment, the impurity element introduced into the polysilicon film 103 uniformly diffuses in the thickness direction of the polysilicon film 103.

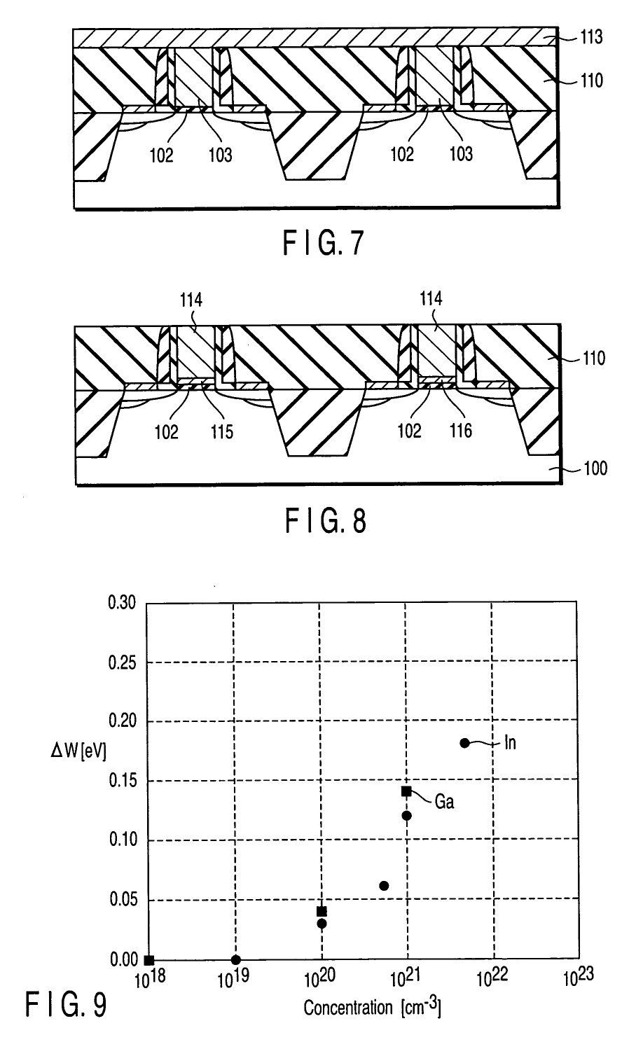

Next. As shown in FIG. 7, a nickel (a second metallic element) film (Ni film) is formed as a metal film 113 by PVD.

Next, as shown in FIG. 8, heat treatment is performed at 400° C. for 30 seconds. By this heat treatment, the Ni film 113 reacts with the polysilicon film 103, and thereby an Ni silicide film is formed as a metal silicide film 114. Further, by this heat treatment, in the n type MIS transistor region, the implanted phosphorus (P) is precipitated in an interface between the gate insulating film 102 and the metal silicide film 114, and thereby an impurity layer 115 containing phosphorus is formed. In the p type MIS transistor region, the implanted indium (In) is precipitated in an interface between the gate insulating film 102 and the metal silicide film 114, and thereby an impurity layer 116 containing indium is formed. Thereafter, unreacted Ni is removed by a mixed solution of sulfuric acid and hydrogen peroxide.

As described above, in the n type MIS transistor region, a gate electrode having the impurity layer 115 formed of phosphorus (P) or arsenic (As) and the Ni silicide film 114 is formed. In the p type MIS transistor region, a gate electrode having the impurity layer 116 formed of indium (In) and the Ni silicide film 114 is formed. The work function of the impurity layer 115 formed of phosphorus (P) or arsenic (As) is lower than the work function of the Ni silicide film 114 by about 0.2 eV. The work function of the impurity layer 116 formed of indium (In) is higher than the work function of the Ni silicide film 114 by about 0.2 eV. The work function of the gate electrode depends on the work function in its portion contacting the gate insulating film. Therefore, it is possible to set the work function of the gate electrode of the p type MIS transistor to be higher than the work function of the gate electrode of the n type MIS transistor.

As described above, according to the embodiment of the present invention, In is introduced as impurity element into the polysilicon film 103 in the p type MIS transistor region. Using In like this enables formation of a MIS transistor having excellent property and reliability. This point is explained as follows.

In the step shown in FIG. 6, if boron (B) is implanted instead of indium (In), it was found that in the heat treatment in FIG. 8, Ni in the Ni silicide film 114 is diffused into the silicon substrate 100. The reason why such diffusion occurs is considered below.

Suppose that a silicon oxide film, polysilicon film and Ni film are stacked on the silicon substrate, and thereafter an Ni silicide film is formed by heat treatment. In such a case, impurity elements which exceed the solubility limit are discharged from the Ni silicide film, and precipitated in the interface between the Ni silicide film and the polysilicon film. Then, when the polysilicon film is entirely transformed into the Ni silicide film, the impurity elements are precipitated in the interface between the Ni silicide film and the silicon oxide film. As a result, in the n type MIS transistor region, P or As is precipitated in the interface between the silicide film and the silicon oxide film, and in the p type MIS transistor region, B is precipitated in the interface between the silicide film and the silicon oxide film. As described above, if a silicon oxide film is used as gate insulating film, B does not diffuse into the silicon substrate, and it is possible to precipitate impurity elements in the interface between the silicide film and the silicon oxide film.

However, if an Hf oxide film or a Zr oxide film is used as gate insulating film, the following problem arises.

Generally, Zr oxides and Hf oxides are thermally stable in comparison with Ti oxides and easy to use as gate insulating film. This is because Zr oxides and Hf oxides do not easily react with Si, while Ti oxides easily react with Si. This can be thermodynamically expressed as follows:
TiO₂+2Si→SiO₂+TiSi ΔG<0 (1)
ZrO₂+2Si→SiO₂+ZrSi ΔG>0 (2)
HfO₂+2Si→SiO₂+HfSi ΔG>0 (3)

As shown in formula (1), the amount of change ΔG of Gibbs free energy when TiO₂ is reduced by Si has a negative value. In comparison with this, as shown in formulae (2) and (3), the amount of change of Gibbs free energy when ZrO₂ or HfO₂ is reduced by Si has a positive value. Therefore, in the reaction of formula (1), the state of the right side of the formula is thermodynamically more stable than the state of the left side. In the reactions of formulas (2) and (3), the state of the left side of the formula is thermodynamically more stable than the state of the right side.

However, the circumstances change in the system containing B. It is known that Ti, Zr and Hf react with B to generate a thermally stable compound. Therefore, if Si and B exist together, Ti oxides, Zr oxides and Hf oxides are reduced. This can be thermodynamically expressed as follows:
TiO₂+Si+2B→SiO₂+TiB₂ ΔG<0 (4)
ZrO₂+Si+2B→SiO₂+ZrB₂ ΔG<0 (5)
HfO₂+Si+2B→SiO₂+HfB₂ ΔG<0 (6)

As is clear from formulas (4)-(6), in all of TiO₂, ZrO₂ and HfO₂, the amount of change of Gibbs free energy has a negative value. Specifically, TiB₂, ZrB₂ and HfB₂ are thermodynamically more stable than TiO₂, ZrO₂ and HfO₂.

Therefore, if a Zr oxide or an Hf oxide is used as gate insulating film and B is used as impurity element, the Zr oxide or Hf oxide is undesirably reduced. Since Zr oxides and Hf oxides have a high barrier property, they can suppress diffusion of Ni into the silicon substrate. However, if the Zr oxide and the Hf oxide are reduced, they cannot suppress diffusion of Ni into the silicon substrate. As a result, as described above, if B ions are implanted instead of In ions in the step shown in FIG. 6, Ni in the Ni silicide film 114 in the heat treatment of FIG. 8 diffuses into the silicon substrate 100.

If Ga (gallium) or In (indium) is used as p type impurity instead of B, it is possible to prevent the above diffusion. If Ga or In is used, the following formulae are established:
MeO₂+Si+2Ga→SiO₂+MeGa₂ ΔG>0 (7)
MeO₂+Si+2In→SiO₂+MeIn₂ ΔG>0 (8)
Me is Zr or Hf.

As is clear from formulae (7) and (8), The Gibbs free energy of the system including a metal oxide (MeO₂) containing a metallic element (Me) and an impurity element (Ga or In) and silicon (Si) is smaller than the Gibbs free energy of the system including a compound containing the metallic element (Me) and the impurity element (Ga or In) and a silicon oxide (SiO₂). Specifically, in the reactions indicated by formulae (7) and (8), the amount of change of the Gibbs free energy has a positive value, and MeO₂ (ZrO₂ or HfO₂) can stably exist. Therefore, If a Ze oxide film or an Hf oxide film is used as gate insulating film, the Zr oxide film or the Hf oxide film can prevent diffusion of Ni in the Ni silicide film into the silicon substrate.

Also in the case where a metal silicate is used as gate insulating film, using Ga or In instead of B enables prevention of the above diffusion.

If a metal silicate is used as gate insulating film, the following formulae are established:
MeSiO₄+Si+2B→2SiO₂+MeB₂ ΔG<0 (9)
MeSiO₄+Si+2Ga→2SiO₂+MeGa₂ ΔG>0 (10)
MeSiO₄+Si+2In→2SiO₂+MeIn₂ ΔG>0 (11)
Me is Zr or Hf.

As is clear from formulae (10) and (11), the Gibbs free energy of the system including a metal silicate (MeSiO₄) containing a metallic element (Me) and an impurity element (Ga or In) and silicon (Si) is smaller than the Gibbs free energy of the system including a compound containing the metallic element (Me) and the impurity element (Ga or In) and a silicon oxide (SiO₂). Specifically, in the reactions expressed by the formulae (10) and (11), the amount of change of the Gibbs free energy has a positive value, and MeSiO₄ (ZrSiO₄ or HfSiO₄) can stably exist.

Further, also in the case where a metal silicate containing nitrogen (hereinafter referred to as “MeSiON” for convenience), using Ga or In instead of B enables prevention of the above diffusion.

Since nitrogen introduced into a metal silicate is in the state of being bonded to silicon, the MeSiON is considered as having a state where MeSiO₄ and Si₃N₄ coexist. Therefore, if a metal silicate containing nitrogen is used as gate insulating film, the following formulae are established:
4MeSiO₄+Si₃N₄+Si+12B→8SiO₂+4MeB₂+4BN ΔG<0 (12)
4MeSiO₄+Si₃N₄+Si+12Ga→8SiO₂+4MeGa₂+4GaN ΔG>0 (13)
4MeSiO₄+Si₃N₄+Si+12In→8SiO₂+4MeIn₂+4InN ΔG>0 (14)
Me is Zr or Hf.

As is clear from the formulae (13) and (14), the Gibbs free energy of the system including a metal silicate (MeSiON (MeSiO₄+Si₃N₄)) containing a metallic element (Me) and nitrogen and an impurity element (Ga or In) and silicon (Si) is smaller than the Gibbs free energy of the system including a compound containing the metallic element (Me) and the impurity element (Ga or In), a compound containing the impurity element (Ga or In) and nitrogen, and a silicon oxide (SiO₂). Specifically, in the reactions expressed by the formulae (13) and (14), the amount of change of the Gibbs free energy has a positive value, and MeSiON (ZrSiON or HfSiON) can stably exist.

FIG. 9 is a diagram illustrating a relationship between concentrations of the impurity elements (In or Ga) existing in the interface between the Ni silicide film and the Hf oxide film and the amounts of change (AW) of the work functions. As shown in FIG. 9, with respect to both In and Ga, the work function increases when the impurity concentration exceeds about 1×10¹⁹ cm⁻³.

Although In and Ga are p type impurities, their solubility limit concentrations in Si are about 7×10¹⁸ cm⁻³, which is much lower than the solubility limit concentration of B, 1×10²⁰ cm⁻³. Therefore, In and Ga are not suitable for a high-concentration p type diffusion layer (such as a source/drain p type diffusion layer) and a high-concentration p type polysilicon film (such as a p type polysilicon film for a gate electrode). Therefore, B is generally used as p type impurity (acceptor) in silicon, and In and Ga are not used. In this embodiment, In or Ga is used as metal layer for defining the work function of the gate electrode, not as acceptor, and thus their low solubility limit does not cause any problem. In other words, using In or Ga which are hardly used as p type impurity in silicon as metal layer can avoid the abovementioned problems due to use of B.

As described above, according to this embodiment, In or Ga is introduced into the polysilicon film in the p type MIS transistor region, and the work function of the gate electrode is defined by the impurity layer containing In or Ga. Using In or Ga as described above can prevent reduction of the metal oxide film or metal silicate film used as gate insulating film. Therefore, the barrier function of the metal oxide film and the metal silicate film is maintained, and thus it is possible to prevent diffusion of the metal element in the metal silicide film into the silicon substrate. Thus, according to the embodiment, it is possible to optimize the work function of the gate electrode, without producing an adverse effect on the property and reliability of the transistor.

In the above embodiment, although one of In and Ga is introduced as impurity element into the polysilicon film, both In and Ga may be introduced into the polysilicon film.

Further, in the above embodiment, although Hf and Zr are mentioned as examples of the metallic element contained in the gate insulating film, the gate insulating film may contain other metallic elements. Generally, an insulating film (such as a metal oxide film and metal silicate film) containing a metallic element selected from Hf, Zr, La, Ce, Pr, Nd, Pm, Sm, Eu, Gd, Tb, Dy, Ho, Er and Lu can be used as gate insulating film.

Further, in the above embodiment, although an Ni silicide film (NiSi film, Ni₂Si film) is used as metal silicide film, other films may be used, such as a Pt₂Si film, PtSi film, Pd₂Si film, PdSi film, CO₂Si film, CoSi film, and CoSi₂ film. Generally, it is possible to use a metal silicide film containing a metal element selected from Ni, Pd, Pt, Co, Ti, Zr and Hf.

Further, in the above embodiment, although impurity elements are introduced into a polysilicon film after patterning the polysilicon film as shown in FIGS. 5 and 6, impurity elements may be introduced into the polysilicon film before patterning the polysilicon film.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a semiconductor substrate;
a gate insulating film which is provided on the semiconductor substrate and contains a first metallic element and oxygen; and
a gate electrode which is provided on the gate insulating film and includes a metal silicide film containing a second metallic element, and an impurity layer interposed between the gate insulating film and the metal silicide film and containing a p type impurity element,
wherein a Gibbs free energy of a first system including an insulator containing the first metallic element and oxygen, the p type impurity element and silicon is smaller than a Gibbs free energy of a second system including a compound containing the first metallic element and the p type impurity element, and a silicon oxide.

2. A semiconductor device according to claim 1, wherein the gate insulating film further contains silicon.

3. A semiconductor device according to claim 1, wherein the p type impurity element is selected from In and Ga.

4. A semiconductor device according to claim 1, wherein the first metallic element is selected from Hf, Zr, La, Ce, Pr, Nd, Pm, Sm, Eu, Gd, Tb, Dy, Ho, Er and Lu.

5. A semiconductor device according to claim 1, wherein the second metallic element is selected from Ni, Pd, Pt, Co, Ti, Zr and Hf.

6. A semiconductor device according to claim 1, wherein a work function of the gate electrode is defined by a work function of the impurity layer.

7. A semiconductor device according to claim 1, wherein a work function of the impurity layer is higher than a work function of the metal silicide film.

8. A semiconductor device comprising:
a semiconductor substrate;
a gate insulating film which is provided on the semiconductor substrate and contains a first metallic element, oxygen and nitrogen; and
a gate electrode which is provided on the gate insulating film and includes a metal silicide film containing a second metallic element, and an impurity layer interposed between the gate insulating film and the metal silicide film and containing a p type impurity element,
wherein a Gibbs free energy of a first system including an insulator containing the first metallic element, oxygen and nitrogen, the p type impurity element and silicon is smaller than a Gibbs free energy of a second system including a compound containing the first metallic element and the p type impurity element, a compound containing the p type impurity element and nitrogen, and a silicon oxide.

9. A semiconductor device according to claim 8, wherein the gate insulating film further contains silicon.

10. A semiconductor device according to claim 8, wherein the p type impurity element is selected from In and Ga.

11. A semiconductor device according to claim 8, wherein the first metallic element is selected from Hf, Zr, La, Ce, Pr, Nd, Pm, Sm, Eu, Gd, Tb, Dy, Ho, Er and Lu.

12. A semiconductor device according to claim 8, wherein the second metallic element is selected from Ni, Pd, Pt, Co, Ti, Zr and Hf.

13. A semiconductor device according to claim 8, wherein a work function of the gate electrode is defined by a work function of the impurity layer.

14. A semiconductor device according to claim 8, wherein a work function of the impurity layer is higher than a work function of the metal silicide film.

15. A method of manufacturing a semiconductor device comprising:
forming a gate insulating film containing a first metallic element and oxygen on a semiconductor substrate;
forming a silicon film on the gate insulating film;
introducing a p type impurity element into the silicon film;
forming a metal film containing a second metallic element on the silicon film; and
forming a metal silicide film containing the second metallic element by reaction between the silicon film and the metal film, and an impurity layer containing the p type impurity element between the gate insulating film and the metal silicide film,
wherein a Gibbs free energy of a first system including an insulator containing the first metallic element and oxygen, the p type impurity element and silicon is smaller than a Gibbs free energy of a second system including a compound containing the first metallic element and the p type impurity element, and a silicon oxide.

16. A method according to claim 15, wherein the gate insulating film further contains silicon.

17. A method of manufacturing a semiconductor device comprising:
forming a gate insulating film containing a first metallic element, oxygen and nitrogen on a semiconductor substrate;
forming a silicon film on the gate insulating film;
introducing a p type impurity element into the silicon film;
forming a metal film containing a second metallic element on the silicon film; and
forming a metal silicide film containing the second metallic element by reaction between the silicon film and the metal film, and an impurity layer containing the p type impurity element between the gate insulating film and the metal silicide film,
wherein a Gibbs free energy of a first system including an insulator containing the first metallic element, oxygen and nitrogen, the p type impurity element and silicon is smaller than a Gibbs free energy of a second system including a compound containing the first metallic element and the p type impurity element, a compound containing the p type impurity element and nitrogen, and a silicon oxide.

18. A method according to claim 17, wherein the gate insulating film further contains silicon.
